(19) United States
(12) Patent Application Publication
(10) Pub. No.: US 2009/0184768 A1
(43) Pub. Date: Jul. 23, 2009

(54) Attenuation Compensating Circuit

(75) Inventor: Daisuke Yamazaki, Kawasaki (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 12/206,070

(22) Filed: Sep. 8, 2008

(30) Foreign Application Priority Data
Jan. 17, 2008 (JP) 2008-008354

(51) Int. Cl. H03G 3/30

(52) U.S. Cl. 330/284

(57) ABSTRACT

An attenuation compensating circuit includes a detector and a stabilizer. The detector has a dummy capacitor corresponding to a capacitor connected to an input terminal of an amplifier and, by detecting the degree of attenuation of a dummy signal passing through the dummy capacitor, detects the degree of attenuation when a signal to be amplified passes through the capacitor connected to the amplifier. The stabilizer has two dummy amplifiers and causes a voltage difference between the input voltages of the dummy amplifiers, where the voltage difference corresponds to the degree of attenuation detected by the detector. The stabilizer controls a bias voltage for setting gain of the dummy amplifier so that a product of the voltage difference of the input voltage and the gain of the dummy amplifier is equivalent to the difference of the voltages output by the dummy amplifiers and supplies the bias voltage to the amplifier.

### CROSS-REFERENCE TO RELATED APPLICATIONS

This application is based upon and claims the benefit of priority from the prior Japanese Patent Application No. 2008-008354, filed on Jan. 17, 2008, the entire contents of which are incorporated herein by reference.

### BACKGROUND OF THE INVENTION

1. Field of the Invention

The present invention relates to an attenuation compensating circuit that compensates attenuation of an amplifier.

2. Description of the Related Art

Conventionally, in an amplifying device using a metal-oxide-semiconductor field-effect transistor (MOSFET), a reference current/voltage circuit is known that suppresses variations in amplification gain. This reference current/voltage circuit includes a first MOSFET and a second MOSFET having nearly identical characteristics to those of the first MOSFET and either the source or the drain thereof is connected to a reference resistor. Sources of the MOSFETs, or the source of the first MOSFET and the reference resistor connected to the source of the second MOSFET, are commonly connected. Further, a control unit is provided that controls a resultant current of currents flowing through the MOSFETs so that a ratio of the currents flowing through the MOSFETs is kept at a predetermined value and a potential is applied across the reference resistor that is substantially equivalent to a voltage difference between a gate-source voltage of the first MOSFET and the gate-source voltage of the second MOSFET. The reference current/voltage circuit is configured to use the resultant current controlled by the control unit as a reference current and the voltage at a terminal of the commonly connected sources of these MOSFETs as a reference voltage (see, for example, Japanese Patent Application Laid-Open Publication No. H10-49244).

A variable gain amplifying circuit is known that is configured to input a signal to be amplified to the amplifier by way of a capacitor. This amplifying circuit includes a first field-effect transistor (FET), where the drain thereof is connected to a power source terminal by way of a first resistor and the source thereof is connected to a ground terminal by way of a second resistor, and further includes a second FET connected in parallel with the first resistor. A signal from an upstream circuit is input to a gate terminal of the first FET by way of a capacitor (see, for example, Japanese Patent Application Laid-Open Publication No. S63-123206).

However, with a configuration where a signal to be amplified is input to the gate terminal of the FET by way of a capacitor, as with the amplifying circuit disclosed in Japanese Patent Application Laid-Open Publication No. S63-123206, the signal input is capacitance-divided by the capacitance of the capacitor connected to the gate terminal (hereinafter, G connected capacitor, the capacitance there indicated as C2), gate-source parasitic capacitance (hereinafter, G-S parasitic capacitance, the value thereof indicated as Cgs), and gate-drain parasitic capacitance (hereinafter, G-D parasitic capacitance, the value thereof indicated as Cgd). Therefore, the signal is input to the gate terminal after attenuation by a magnitude of [C2/(C2+Cgs+Cgd)].

Generally in many cases, to pass a high speed signal, the G connected capacitor is configured by a metal-insulator-metal (MIM) capacitor (interconnect capacitor). Meanwhile, the G-S parasitic capacitance and the G-D parasitic capacitance are the capacitance with respect to the bulk. Therefore, the capacitance of the G connected capacitor, the G-S parasitic capacitance, and the G-D parasitic capacitance independently vary, thereby causing [C2/(C2+Cgs+Cgd)] to vary, and the gain of the amplifier as a whole does not become constant. The same problem arises with a configuration involving the use of the reference current/voltage circuit disclosed in Japanese Patent Application Laid-Open Publication No. H10-49244.

Variation of [C2/(C2+Cgs+Cgd)] may be suppressed by making the capacitance of the G connected capacitor sufficiently large with respect to a sum of the G-S parasitic capacitance and the G-D parasitic capacitance. However, by increasing the capacitance of the G connected capacitor, the parasitic capacitance of the G connected capacitor increases and therefore, the bandwidth of the amplifier is restricted. Further, as the MIM generally has poor capacitive density with respect to area, the MIM becomes a factor inhibiting size reductions of integrated circuits.

### SUMMARY OF THE INVENTION

It is an object of the present invention to at least solve the above problems in the conventional technologies.

An attenuation compensating circuit according to one aspect of the present invention includes a detector that detects a degree of attenuation when a signal to be amplified passes through a capacitor; and a stabilizer that controls a bias voltage supplied to an amplifier based on the degree of attenuation detected by the detector.

The other objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a diagram of an attenuation compensating circuit and an amplifier according to an embodiment;

FIG. 2 is a circuit diagram of one example of the amplifier;

FIG. 3 is a circuit diagram of one example of the generator;

FIG. 4 is a circuit diagram of one example of the detector;

FIG. 5 is a circuit diagram of one example of the logical element;

FIG. 6 is a circuit diagram of one example of the stabilizer;

FIG. 7 is a circuit diagram of one example of the bias circuit;

FIG. 8 is a timing chart for description of the compensating circuit;

FIG. 9 is a circuit diagram of a generalized example of the amplifier;

FIG. 10 is a circuit diagram of the detector in the case of generalizing the amplifier;

FIG. 11 is a circuit diagram of the stabilizer in the case of generalizing the amplifier; and

FIG. 12 is a circuit diagram of an example of the amplifier as a low-noise amplifying circuit.

### DETAILED DESCRIPTION OF THE PREFERRED EMBODIMENTS

Referring to the accompanying drawings, exemplary embodiments according to the present invention are explained in detail below. In the drawings, capacitance values, resistance values, voltage values, and current values of respective parts are shown in parentheses. Further, the present invention is not limited to the following embodiments.

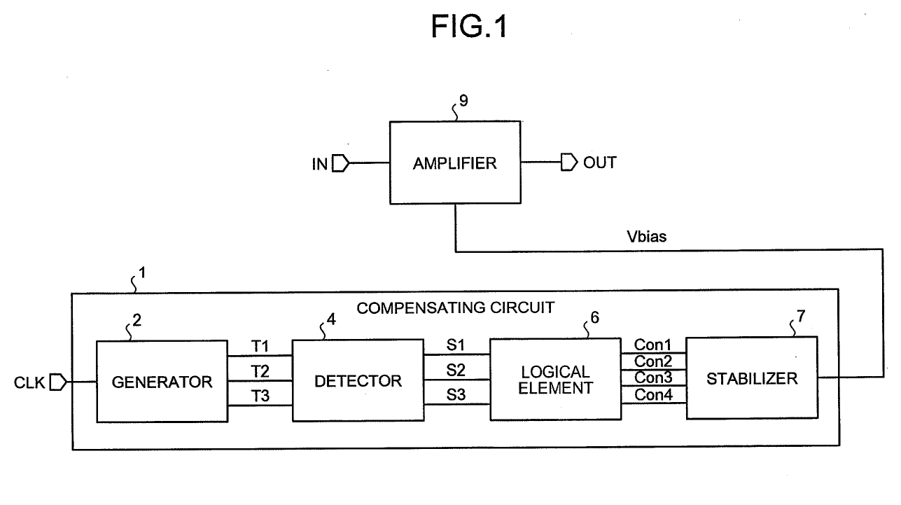

FIG. 1 is a diagram of an attenuation compensating circuit and an amplifier according to an embodiment. As shown in FIG. 1, the attenuation compensation circuit (hereinafter, compensating circuit) 1 includes a generator 2, a detector 4, a logical element 6, and a stabilizer 7. The amplifier 9 capacitance-divides, amplifies, and outputs a signal input from an external source. The generator 2 receives input of a clock signal CLK. The generator 2 generates, for example, three timing signals T1, T2, and T3 based on the clock signal CLK. The detector 4 detects the degree of attenuation of the signal due to capacitance division by the amplifier 9 and generates detection signals S1, S2, and S3.

Operation of the detector 4 is controlled by the timing signals T1, T2, and T3 generated by the generator 2. The logical element 6 performs a logical operation on the detection signals S1, S2, and S3 output from the detector 4 and converts these signals to codes Con1, Con2, Con3, and Con4. The stabilizer 7 controls a bias voltage Vbias supplied to the amplifier 9, based on the codes of the control signals Con1, Con2, Con3, and Con4 output from the logical element 6. With the bias voltage Vbias being controlled by the stabilizer 7 according to the degree of attenuation due to the capacitance division of the amplifier 9, attenuation due to the capacitance division of the amplifier 9 is compensated and the gain is kept constant.

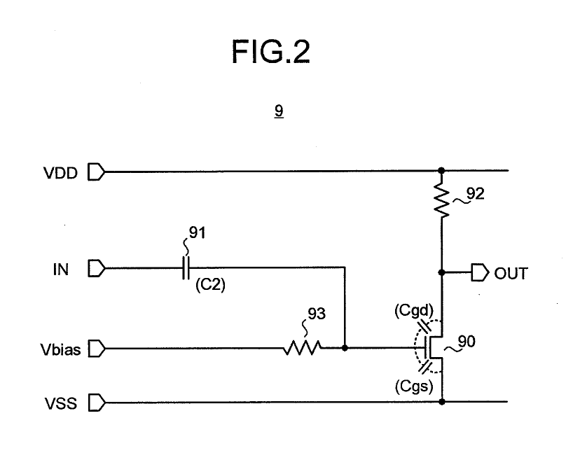

FIG. 2 is a circuit diagram of one example of the amplifier. As shown in FIG. 2, the amplifier 9 includes an amplifying transistor 90, a first G connected capacitor 91, a first resistor 92, and a second resistor 93. An amplifying circuit composed of the amplifying transistor 90, the first resistor 92, and the second resistor 93 is coupled with an upstream circuit not shown by way of the first G connected capacitor 91. This amplifying circuit is applicable, for example, as a transmitting power amplifier of a wireless communication device and a driver that drives the power amplifier. A drain terminal of the amplifying transistor 90 is connected to an output terminal of the amplifier 9 and a power source by way of the first resistor 92. A source terminal of the amplifying transistor 90 is grounded. A gate terminal of the amplifying transistor 90 is connected to an input terminal of the amplifier 9 by way of the G connected capacitor 91. The capacitance of the first G connected capacitor 91 is indicated as C2.

A gain-setting bias voltage Vbias is applied by the stabilizer 7 to the gate terminal of the amplifying transistor 90 by way of the second resistor 93. Since the amplifying transistor 90 is a grounded-source amplifier, the voltage of the gate terminal to which the signal to be amplified is input and the voltage of the terminal for setting the gain become equivalent. Accordingly, the gate terminal of the amplifying transistor 90 may be used as a terminal for setting the gain. In the amplifier 9, the input signal is capacitance-divided by the capacitance C2 of the first G connected capacitor 91, and the G-S parasitic capacitance Cgs and the G-D parasitic capacitance Cgd of the amplifying transistor 90. Therefore, attenuation of the input signal as a result of passing through the first G connected capacitor 91 may be expressed by equation (1) and the input signal is input to the gate terminal of the amplifying transistor 90.

C2/(C2+Cgs+Cgd) (1)

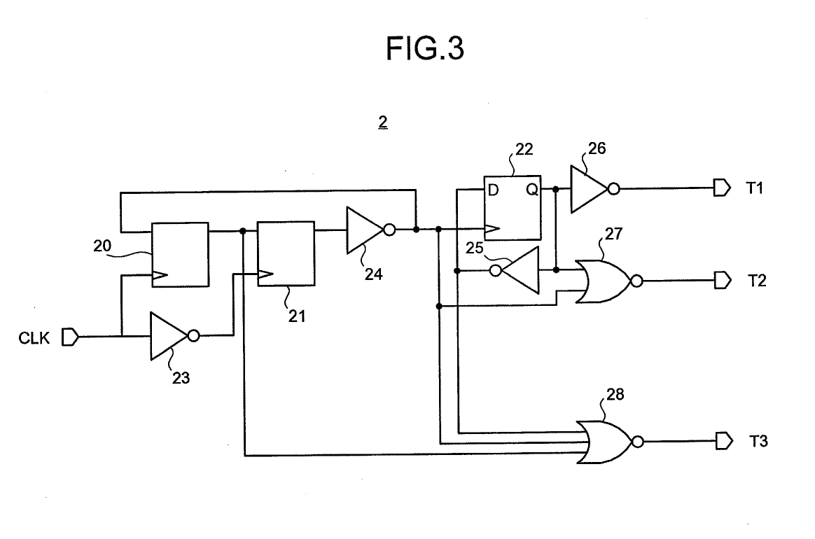

FIG. 3 is a circuit diagram of one example of the generator. As shown in FIG. 3, the generator 2 includes a first latch circuit 20, a second latch circuit 21, a D-type flip-flop circuit 22, first to fourth inverters 23, 24, 25, and 26, a first NOR gate 27, and a second NOR gate 28. A clock terminal of the first latch circuit 20 receives the clock signal CLK. The clock terminal of the second latch circuit 21 receives the clock signal CLK inverted by way of the first inverter 23.

The input terminal of the second latch circuit 21 is connected to the output terminal of the first latch circuit 20. The input terminal of the second inverter 24 is connected to the output terminal of the second latch circuit 21. The output terminal of the second inverter 24 is connected to the input terminal of the first latch circuit 20 and the clock terminal of the D-type flip-flop circuit 22. A Q terminal of the D-type flip-flop circuit 22 is connected to the input terminal of the fourth inverter 26 and the input terminal of the third inverter 25. The output terminal of the third inverter 25 is connected to a D terminal of the D-type flip-flop circuit 22.

The fourth inverter 26 outputs a first timing signal T1 as a dummy signal. Two input terminals of the first NOR gate 27 are connected to the Q terminal of the D-type flip-flop circuit 22 and the output terminal of the second inverter 24, respectively. The NOR gate 27 outputs a second timing signal T2. Three input terminals of the second NOR gate 28 are connected to the output terminal of the third inverter 25, the output terminal of the second inverter 24, and the output terminal of the first latch circuit 20, respectively. The second NOR gate 28 outputs the third timing signal T3.

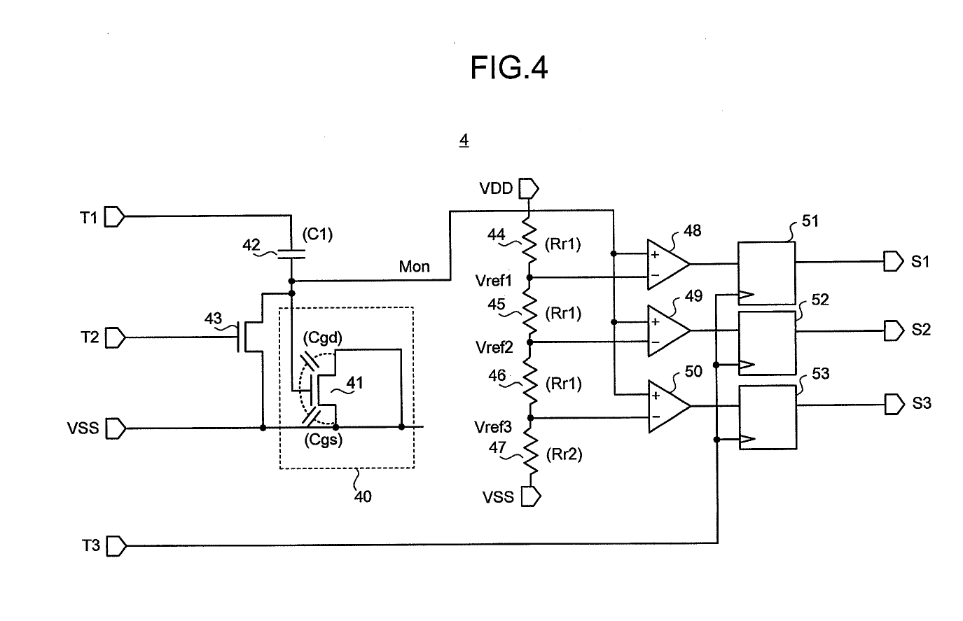

FIG. 4 is a circuit diagram of one example of the detector. As shown in FIG. 4, the detector 4 includes a third dummy amplifier 40 having a third dummy amplifying transistor 41, a second G connected capacitor 42 as a dummy capacitor, a resetting transistor 43, first to fourth voltage-dividing resistors 44, 45, 46, and 47, first to third comparators 48, 49, and 50, and third to fifth latch circuits 51, 52, and 53. The second G connected capacitor 42 is connected to the gate terminal of the third dummy amplifying transistor 41. The capacitance of the second G connected capacitor 42 is indicated as C1.

The first timing signal T1 is input to the gate terminal of the third dummy amplifying transistor 41 by way of the second G connected capacitor 42. The source and drain terminals of the third dummy amplifying transistor 41 are grounded. The voltage of the first timing signal T1 is a source voltage VDD or a ground voltage VSS. The first timing signal T1, in passing through the second G connected capacitor 42, is capacitance-divided by the capacitance C1 of the second G connected capacitor 42 and the G-S parasitic capacitance Cgs and the G-D parasitic capacitance Cgd of the third dummy amplifying transistor 41.

Therefore, the gate voltage of the third dummy amplifying transistor 41 becomes the voltage of the first timing signal T1 attenuated by a degree expressed by equation (2).

C1/(C1+Cgs+Cgd) (2)

By configuring the second G connected capacitor 42 and the first G connected capacitor 91 of the amplifier 9 of identical MIM capacitors so that the respective capacitances thereof are made equal and by configuring the third dummy amplifying transistor 41 and the amplifying transistor 90 of the amplifier 9 to be the same size and formed close to each other by same process, the attenuation of the first timing signal T1 and the attenuation of the input signal of the amplifier 9 become equivalent (see equation (2) and equation (1)). Namely, variation of the attenuation of the input signal due to the capacitance division in the amplifier 9 may be monitored by the second G connected capacitor 42 and the third dummy amplifying transistor 41.

Accordingly, the second G connected capacitor 42 and the first G connected capacitor 91, and the third dummy amplifying transistor 41 and the amplifying transistor 90, are formed to satisfy the conditions above, respectively. The gate voltage of the third dummy amplifying transistor 41 is extracted as a monitoring signal Mon and the voltage of the monitoring signal Mon (hereinafter, monitoring voltage Vmon) is detected by the voltage-dividing resistors 44, 45, 46, and 47 and the comparators 48, 49, and 50.

The monitoring voltage Vmon is reset by the resetting transistor 43. The source terminal of the resetting transistor 43 is grounded. The drain terminal of the resetting transistor 43 is connected to the gate terminal of the third dummy amplifying transistor 41. The gate terminal of the resetting transistor 43 receives input of the second timing signal T2.

The first to fourth voltage-dividing resistors 44, 45, 46, and 47 are connected sequentially and in series between the power source and the ground. The resistance of the first to third voltage-dividing resistors 44, 45, and 46 is indicated as Rr1 and the resistance of the fourth voltage-dividing resistor 47 is indicated as Rr2. The voltage of a node between the first voltage-dividing resistor 44 and the second voltage-dividing resistor 45 is indicated as a first reference voltage Vref1, the voltage of the node between the second voltage-dividing resistor 45 and the third voltage-dividing resistor 46 is indicated as a second reference voltage Vref2, and the voltage of the node between the third voltage-dividing resistor 46 and the fourth voltage-dividing resistor 47 is indicated as a third reference voltage Vref3.

The first reference voltage Vref1, the second reference voltage Vref2, and the third reference voltage Vref3 may be expressed by equations (3), (4), and (5), respectively.

Vref1=VDD×(2Rr1+Rr2)/(3Rr1+Rr2) (3)

Vref2=VDD×(Rr1+Rr2)/(3Rr1+Rr2) (4)

Vref3=VDD×Rr2/(3Rr1+Rr2) (5)

The first comparator 48 compares the monitoring voltage Vmon and the first reference voltage Vref1 and outputs a high-level signal when the monitoring voltage Vmon is higher than the first reference voltage Vref1 and a low-level signal when the monitoring voltage Vmon is lower than the first reference voltage Vref1. The second comparator 49 compares the monitoring voltage Vmon and the second reference voltage Vref2 and similarly outputs the high-level or the low-level signal. The third comparator 50 compares the monitoring voltage Vmon and the third reference voltage Vref3 and similarly outputs the high-level or the low-level signal.

The third timing signal T3 is input to each clock terminal of the third to fifth latch circuits 51, 52, and 53. The third latch circuit 51 latches a logical output from the first comparator 48 and outputs the first detection signal S1. The fourth latch circuit 52 latches the logical output from the second comparator 49 and outputs the second detection signal S2. The fifth latch circuit 53 latches the logical output from the third comparator 50 and outputs the third detection signal S3.

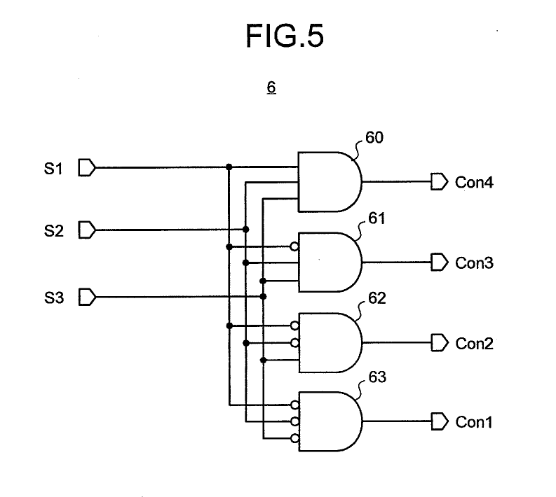

FIG. 5 is a circuit diagram of one example of the logical element. As shown in FIG. 5, the logical element 6 comprises first to fourth AND gates 60, 61, 62, and 63. The fourth AND gate 63 sets the first control signal Con1 to high-level only when none of the first detection signal S1, the second detection signal S2, and the third detection signal S3 are high-level. The third AND gate 62 sets the second control signal Con 2 to high-level only when only the third detection signal S3 is high-level. The second AND gate 61 sets the third control signal Con3 to high level only when only the second detection signal S2 and the third detection signal S3 are high-level. The first AND gate sets the fourth control signal Con4 to high-level only when all of the first detection signal S1, the second detection signal S2, and the third detection signal S3 are high.

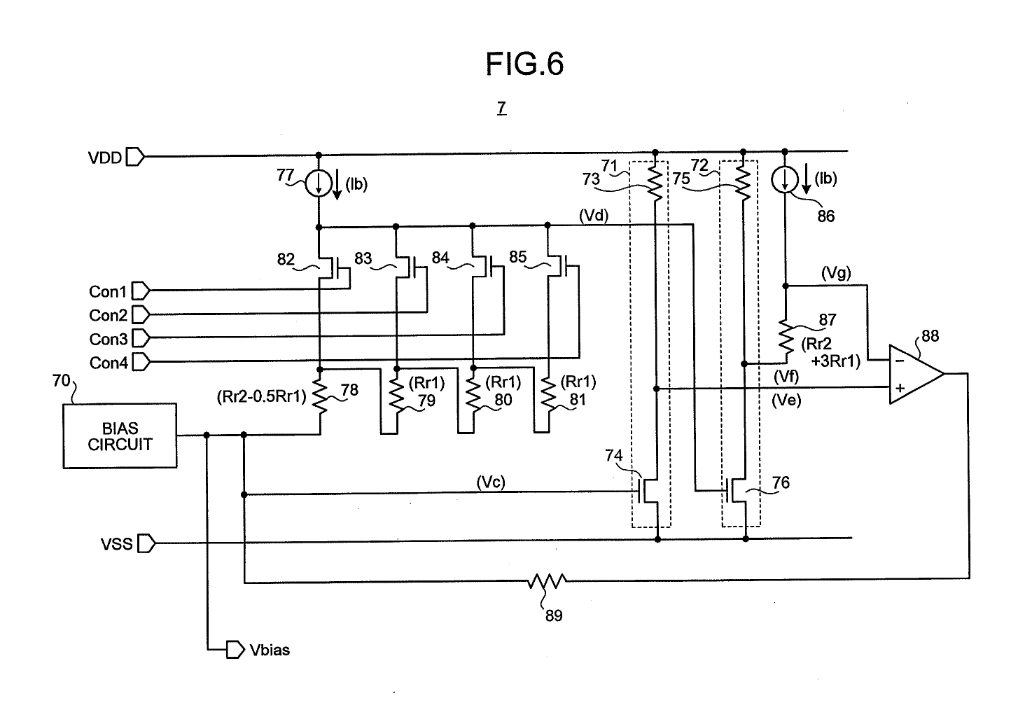

FIG. 6 is a circuit diagram of one example of the stabilizer. As shown in FIG. 6, the stabilizer 7 includes a bias circuit 70, a first dummy amplifier 71 having a third resistor 73 and a first dummy amplifying transistor 74, a second dummy amplifier 72 having a fourth resistor 75 and a second dummy amplifying transistor 76, first and second current sources 77 and 86, first to fourth controlling resistors 78, 79, 80, and 81, first to fourth switching transistors 82, 83, 84, and 85, fifth and sixth resistors 87 and 89, and an operational amplifier 88.

The drain terminal of the first dummy amplifying transistor 74 is connected to the power source by way of the third resistor 73. The source terminal of the first dummy amplifying transistor 74 is grounded. The gate terminal of the first dummy amplifying transistor 74 is connected to one end of the first controlling resistor 78. The other end of the first controlling resistor 78 is connected to the source terminal of the first switching transistor 82 and one end of the second controlling resistor 79. The other end of the second controlling resistor 79 is connected to the source terminal of the second switching transistor 83 and one end of the third controlling resistor 80. The other end of the third controlling resistor 80 is connected to the source terminal of the third switching transistor 84 and one end of the fourth controlling resistor 81. The other end of the fourth controlling resistor 81 is connected to the source terminal of the fourth switching transistor 85.

The first current source 77 is connected between each drain terminal of the first to fourth switching transistors 82, 83, 84, and 85 and the power source. The gate terminal of the first switching transistor 82 receives input of the first control signal Con1. The gate terminal of the second switching transistor 83 receives input of the second control signal Con2. The gate terminal of the third switching transistor 84 receives input of the third control signal Con3. The gate terminal of the fourth switching transistor 85 receives input of the fourth control signal Con4.

The drain terminal of the second dummy amplifying transistor 76 is connected to the power source by way of the fourth resistor 75. The source terminal of the second dummy amplifying transistor 76 is grounded. The gate terminal of the second dummy amplifying transistor 76 is commonly connected to each drain terminal of the first to fourth switching transistors 82, 83, 84, and 85. An inverting input terminal of the operation amplifier 88 is connected to the drain terminal of the second dummy amplifying transistor 76 by way of the fifth resistor 87. The second current source 86 is connected between the inverting input terminal of the operation amplifier 88 and the power source. A non-inverting input terminal of the operational amplifier 88 is connected to the drain terminal of the first dummy amplifying transistor 74.

The output terminal of the operational amplifier 88 is connected to the gate terminal of the first dummy amplifying transistor 74 by way of the sixth resistor 89. The gate terminal of the first dummy amplifying transistor 74 is connected to the bias circuit 70 and the bias circuit 70 gives a bias to the gate terminal of the first dummy amplifying transistor 74. Since both the first dummy amplifying transistor 74 and the second dummy amplifying transistor 76 are a grounded-source amplifier, respective gate terminals thereof are signal input terminals and at the same time, are used as a terminal for setting the gain.

The first dummy amplifying transistor 74 and the second dummy amplifying transistor 76, and the amplifying transistor 90 of the amplifier 9 are of an identical size and are formed close to one another by the same process. The third resistor 73 and the fourth resistor 75, and the first resistor 92 of the amplifier 9 are configured in the same manner and, for example, have an equivalent resistance. The resistance of the first controlling resistor 78 is given as [Rr2−0.5Rr1] and the resistance of the second to fourth controlling resistors 79, 89, and 81 is given as Rr1. The resistance of the fifth resistor 87 is given as [Rr2+3Rr1].

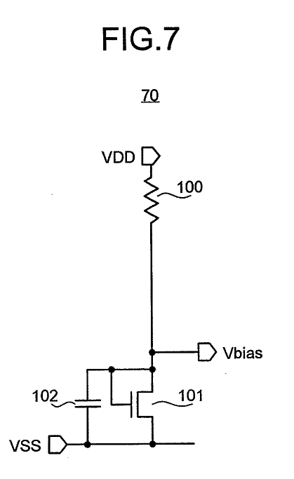

FIG. 7 is a circuit diagram of one example of the bias circuit. As shown in FIG. 7, the bias circuit 70 includes a seventh resistor 100, a transistor 101, and a first capacitor 102. The drain terminal of the transistor 101 is connected to the power source by way of the seventh resistor 100 and at the same time, is connected to the gate terminal of itself. The source terminal of the transistor 101 is grounded. The first capacitor 102 is connected between the drain terminal of the transistor 101 and the ground. The drain voltage of the transistor 101 is applied to the gate terminal of the first dummy amplifying transistor 74 as the bias voltage Vbias. The reference current/voltage circuit disclosed in Japanese Patent Application Laid-Open Publication No. H10-49244 may also be adopted as the bias circuit 70.

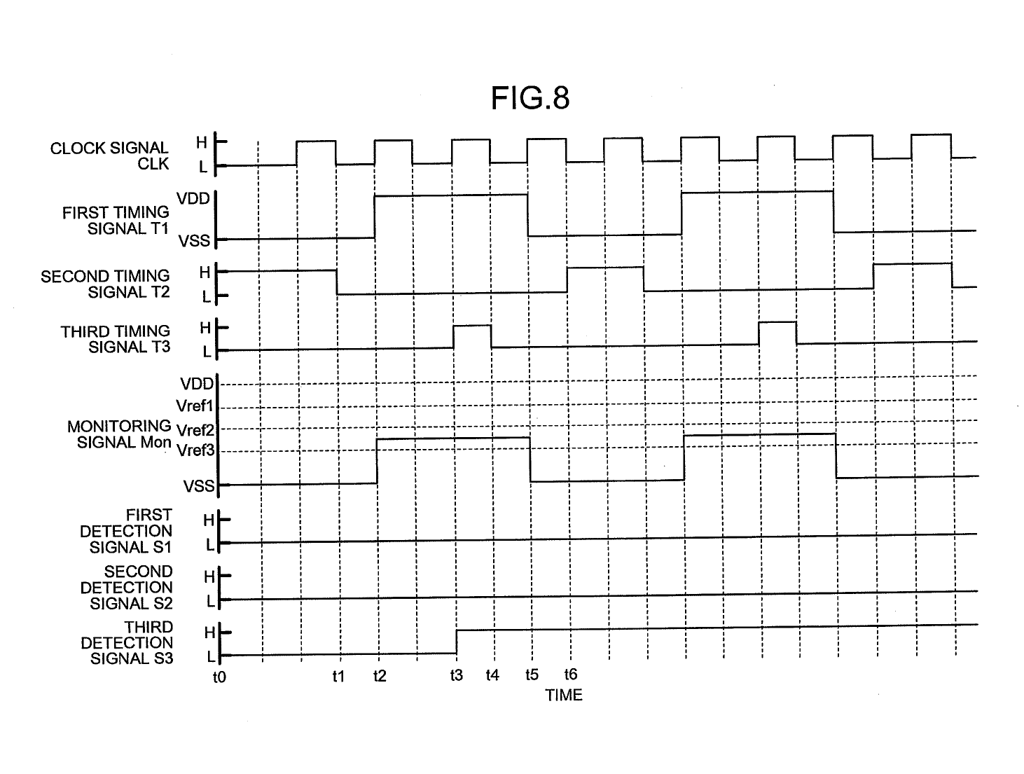

FIG. 8 is a timing chart for description of the compensating circuit. As shown in FIG. 8, from time t0 to t1, the voltage of the first timing signal T1 is the ground voltage VSS, the voltage of the second timing signal T2 is high-level, and the voltage of the third timing signal T3 is low-level. Since the voltage of the second timing signal T3 is high, the resetting transistor 43 is in a conducting state and the compensating circuit 1 is in a reset state. Therefore, the monitoring voltage Vmon is the ground voltage VSS.

At time t1, when the voltage of the second timing signal T2 is switched to low-level in synchronization with a falling edge of the clock signal CLK, the reset is released and the resetting transistor 43 enters a non-conducting state. However, from time t1 to t2 before a subsequent rising edge of the clock signal CLK, since the voltage of the first timing signal T1 remains the ground voltage VSS, the monitoring voltage Vmon as well remains the ground voltage VSS.

At time t2, when the voltage of the first timing signal T1 is switched to the source voltage VDD in synchronization with the rising edge of the clock signal CLK, this causes the monitoring voltage Vmon to rise. At this time, with the resetting transistor 43 still in the non-conducting state, there is no charge flowing from a connection node of the gate terminal of the third dummy amplifying transistor 41 and the second G connected capacitor 42. Therefore, the charge stored in the second G connected capacitor 42 is equivalent to G-S parasitic capacitance and the G-D parasitic capacitance of the third dummy amplifying transistor 41.

If this charge is indicated as Q, then Q may be expressed by equation (6) and from equation (6), the monitoring voltage Vmon may be expressed by equation (7), wherein C1 is the capacitance of the second G connected capacitor 42 and the Cgs and Cgd are the G-S parasitic capacitance and the G-D parasitic capacitance, respectively, of the third dummy amplifying transistor 41.

Q=(VDD−Vmon)C1=(Vmon−VSS)(Cgs+Cgd) (6)

Vmon={C1×VDD+(Cgs+Cgd)×VSS}/(C1+Cgs+Cgd) (7)

When the monitoring voltage Vmon is between the source voltage VDD and the first reference voltage Vref1, the first to third comparators 48, 49, and 50 output the high-level signal. When the monitoring voltage Vmon is between the first reference voltage Vref1 and the second reference voltage Vref2, the first comparator 48 outputs the low-level signal and the second and third comparators 49 and 50 output the high-level signal. When the monitoring voltage Vmon is between the second reference voltage Vref2 and the third reference voltage Vref3, the first and second comparators 48 and 49 output the low-level signal and the third comparators 50 outputs the high-level signal. When the monitoring voltage Vmon is between the third reference voltage Vref3 and the ground voltage VSS, the first to third comparators 48, 49, and 50 output the low-level signal.

During the time after time t2 until time t5 when the voltage of the first timing signal T1 is switched to the ground voltage VSS, from time t3 to t4, the voltage of the third timing signal T3 becomes high. Here, the third to fifth latch circuits 51, 52, and 53 latch output values of the first to third comparators 48, 49, and 50, respectively, and until latching of the next output values of the first to third comparators 48, 49, and 50, retain these values and output the values as the first detection signal S1, the second detection signal S2, and the third detection signal S3, respectively.

After switching of the voltage of the first timing signal T1 to the ground voltage VSS at time t5, when the voltage of the second timing signal T2 again becomes high at time t6, the compensating circuit 1 is again reset. The same operation is repeated thereafter. FIG. 8 depicts an example of the monitoring voltage Vmon being between the second reference voltage Vref2 and the third reference voltage Vref3.

When the monitoring voltage Vmon is between the source voltage VDD and the first reference voltage Vref1, the first detection signal S1, the second detection signal S2, and the third detection signal S3 become high and hence, a code composed of the control signals Con1, Con2, Con3, and Con4 output from the logical element 6 is “0001”. In this 4-bit code system, values of the first control signal Con1, the second control signal Con2, the third control signal Con3, and the fourth control signal Con4 are represented in this order from left to right.

When the monitoring voltage Vmon is between the first reference voltage Vref1 and the second reference voltage Vref2, the output code of the logical element 6 is “0010”. When the monitoring voltage Vmon is between the second reference voltage Vref2 and the third reference voltage Vref3, the output code of the logical element 6 is “0100”. When the monitoring voltage Vmon is between the third reference voltage Vref3 and the ground voltage VSS, the output code of the logical element 6 is “1000”.

In the stabilizer 7, depending on the output code of the logical element 6, any one of the first to fourth switching transistor 82, 83, 84, and 85 enters the conducting state. As described above, information concerning the capacitance of the second G connected capacitor 42 and the sum of the G-S parasitic capacitance and the G-D parasitic capacitance of the third dummy amplifying transistor 41 is conveyed from the detector 4 to the stabilizer 7.

When the output code of the logical element 6 is “0001”, only the fourth switching transistor 85 enters the conducting state; hence, equation (8) holds. Similarly, in respective cases when the output code of the logical element 6 is “0010”, “0100”, and “1000”, only the third switching transistor 84, only the second switching transistor 83, and only the first switching transistor 82, respectively, enter the conducting state and equations (9), (10), and (11) hold.

Where, Vc is the input voltage of the first dummy amplifying transistor 74 and at the same time, is the bias voltage for setting the gain, Vd is the input voltage of the second dummy amplifying transistor 76 and at the same time, is the bias voltage for setting the gain, and Ib is the value of a minute current passed by the first current source 77.

Vd−Vc=Ib(Rr2+2.5Rr1) (8)

Vd−Vc=Ib(Rr2+1.5Rr1) (9)

Vd−Vc=Ib(Rr2+0.5Rr1) (10)

Vd−Vc=Ib(Rr2−0.5Rr1) (11)

Mutual conductance gm of the first dummy amplifying transistor 74 is determined by the voltage Vc. The mutual conductance gm of the second dummy amplifying transistor 76 is determined by the voltage Vd. Since [Vd−Vc] is minute, the gain of the first dummy amplifier 71 and the gain of the second dummy amplifier 72 may be considered as substantially equivalent. If this gain is expressed as −A, equations (12) and (13) hold, where Ve is the drain voltage of the first dummy amplifying transistor 74 and Vf is the drain voltage of the second dummy amplifying transistor 76.

Ve=−A×Vc (12)

Vf=−A×Vd (13)

If left members and right members of the equations (12) and (13) are respectively subtracted and the expression is rearranged, equation (14) may be obtained.

−A(Vd−Vc)=Vf−Ve (14)

In the stabilizer 7, since the output of the operation amplifier 88 is fed back to the input to the first dummy amplifier 71 by way of the sixth resistor 89, a feedback control works so that the input voltage Ve of the non-inverting input terminal of the operational amplifier 88 (same as the drain voltage of the first dummy amplifying transistor 74) and the input voltage Vg of the inverting input terminal will be equivalent. Therefore, if Ve of equation (14) is replaced by Vg, equation (15) may be obtained.

−A(Vd−Vc)=−(Vg−Vf) (15)

If the second current source 86 is configured to pass a current equivalent to that of the first current source 77, the second current source 87 causes the current Ib to flow through the fifth resistor 87 and equation (16) holds.

Vg−Vf=Ib(Rr2+3Rr1) (16)

If equations (16) and (8) are substituted into equation (15) and the equation is solved for the gain A, equation (17) is obtained. Likewise, if, in place of equation (8), equation (9), equation (10), or equation (11) is substituted, equations (18) to (20) are obtained.

A=(Rr2+3Rr1)/(Rr2+2.5Rr1) (17)

A=(Rr2+3Rr1)/(Rr2+1.5Rr1) (18)

A=(Rr2+3Rr1)/(Rr2+0.5Rr1) (19)

A=(Rr2+3Rr1)/(Rr2−0.5Rr1) (20)

Namely, depending on the monitoring voltage Vmon, the gain of the first dummy amplifying transistor 74 is adjusted to any one of the equations (17) to (20). In other words, the gate voltage of the first dummy amplifying transistor 74 is controlled so that such gain may be obtained. Voltage equivalent to the gate voltage of the first dummy amplifying transistor 74 is given to the gate terminal of the amplifying transistor 90 as the bias voltage Vbias for setting the gain of the amplifying transistor 90 of the amplifier 9.

With the first dummy amplifying transistor 74 and the amplifying transistor 90 of the amplifier 9, the third resistor 73 of the stabilizer 7, and the first resistor 92 of the amplifier 9 respectively satisfying the conditions described above, the gain of the amplifying transistor 90 becomes equivalent to that of the first dummy amplifying transistor 74. Therefore, the gain of the amplifying transistor 90 is adjusted to any one of equations (17) to (20).

On the other hand, in the amplifier 9, if the degree of attenuation by the passage of the input signal through the first G connected capacitor 91 is indicated as Aloss, the degree of attenuation Aloss may be expressed by equation (21), where C2 is the capacitance of the first G connected capacitor 91 and Cgs and Cgd are the G-S parasitic capacitance and the G-D parasitic capacitance, respectively, of the amplifying transistor 90.

Aloss=C2/(C2+Cgd+Cgs) (21)

Therefore, if the gain of the amplifier as a whole from the input terminal to the output terminal of the amplifier 9 is indicated as Atotal, the total gain Atotal may be expressed by equation (22).

Atotal=Aloss×A (22)

From equation (22), equation (21), and equations (17) to (20), the total gain Atotal of the amplifier 9 may be expressed by equations (23) to (26).

When Vref1<Vmon<VDD,

Atotal={C2/(C2+Cgd+Cgs)}×{(Rr2+3Rr1)/(Rr2+2.5Rr1)} (23)

When Vref2<Vmon<Vref1,

Atotal={C2/(C2+Cgd+Cgs)}×{(Rr2+3Rr1)/(Rr2+1.5Rr1)} (24)

When Vref3<Vmon<Vref2,

Atotal={C2/(C2+Cgd+Cgs)}×{(Rr2+3Rr1)/(Rr2+0.5Rr1)} (25)

When VSS<Vmon<Vref3,

Atotal={C2/(C2+Cgd+Cgs)}×{(Rr2+3Rr1)/(Rr2−0.5Rr1)} (26)

Although description is made, as one example, of a case in which the monitoring voltage Vmon is between the second reference voltage Vref2 and the third reference voltage Vref3, giving specific numerical values, the present invention is not to be limited to the following numerical values. In the amplifier 9, the capacitance C2 of the first G connected capacitor 91 is given as 100 fF and [Cgs+Cgd] of the amplifying transistor 90 is given as 50 fF. In the detector 4, the capacitance C1 of the second G-connected capacitor 42 is given as 100 fF and [Cgs+Cgd] of the third dummy amplifying transistor 41 is given as 50 fF.

The source voltage VDD is given as 1.2V and the ground voltage VSS is given as 0V. The resistance value Rr1 is given as 1.5 kΩ and the resistance value Rr2 is given as 7.5 kΩ. In this case, from equations (3) to (5), the first reference voltage Vref1, the second reference voltage Vref2, and the third reference voltage Vref3 obtained are 1.05V, 0.9V, and 0.75V, respectively. With substitution of respective numerical values into equation (7), the monitoring voltage Vmon obtained is 0.8V. Therefore, with substitution of the respective numerical values into equation (19), the gain of the first dummy amplifying transistor 74 is a magnitude of 1.45. With the substitution of the respective numerical values into equation (21), attenuation due to the capacitance division in the amplifier 9 is a magnitude of 0.67.

Therefore, from equation (22) or (25), the gain of the amplifier 9 is a magnitude of 0.97. Namely, this indicates that a gain of almost one may be obtained, compensating for the attenuation due to the capacitance division. If the resistance of the first resistor 92 of the amplifier 9 is made two times that of the third resistor 73 of the first dummy amplifier 71 and two times that of the fourth resistor 75 of the second dummy amplifier 72, the gain of the amplifier 9 becomes 1.94 times that of the first dummy amplifier 71 and 1.94 times that of the second dummy amplifier 72.

Here, the reason for the gain of the amplifier 9 being slightly less than one or two is that processing is performed by comparing the monitoring voltage Vmon and the first to third reference voltages (Vref1, Vref2, and Vref3) and digitalizing attenuation due to the capacitance division, based on a correlation of magnitudes thereof. Therefore, by reducing the respective voltage differences in comparing reference voltages with the monitoring voltage Vmon and increasing the number of the reference voltages, accuracy may be enhanced. On the other hand, the increase in the number of reference voltages results in greater resistance of the voltage-dividing resistors and an increased circuit area and therefore, when reducing the size of the compensating circuit 1, the number of reference voltages may be reduced.

The effect of the amplifier 9 on bandwidth is as follows. For example, assuming that, in a manufacturing process, the capacitance C2 of the first G connected capacitor 91 (MIM) and [Cgs+Cgd] of the amplifying transistor 90 vary ±30% relatively. Further assuming that variation in the gain of the amplifier 9 made by this manufacturing process is suppressed to within ±1.5%.

If the degree of attenuation by the passage of the input signal through the first G connected capacitor 91 is given as Aloss, equations (27) and (28) must be satisfied when there is no compensating circuit 1, where Aloss(typ) is the degree of attenuation when there is no variation in gain, Aloss(max) is the degree of attenuation when the gain varies +1.5%, and the Aloss(min) is the degree of attenuation when the gain varies −1.5%.

Aloss(max)/Aloss(typ){C2/(C2+0.7(Cgd+Cgs))}/{C2/(C2+Cgd+Cgs)}<1.015

Therefore, C2>18.6(Cgd+Cgs) (27)

Aloss(min)/Aloss(typ)={C2/(C2+1.3(Cgd+Cgs))}/{C2/(C2+Cgd+Cgs)}>0.995

Therefore, C2>17.4(Cgd+Cgs) (28)

Therefore, the capacitance C2 of the first G connected capacitor 91 must be made 18.6 times as much as [Cgs+Cgd] of the amplifying transistor 90. If it is assumed that the parasitic capacitance of the first G connected capacitor 91 is 10% of the first G connected capacitor 91, the capacitance value is 1.86 times as much as [Cgs+Cgd]. In this case, as compared with the case in which the parasitic capacitance of the first G connected capacitor 91 is 0, the bandwidth of the amplifier is 0.35 times and transfer gain of the signal passing through the first G connected capacitor 91 is 0.95 times. Therefore, GD product becomes 0.33 times (=0.35×0.95).

In the case of a configuration having the compensating circuit 1, if the capacitance C2 of the first G connected capacitor 91 is made 5 times as much as [Cgs+Cgd] of the amplifying transistor 90, the parasitic capacitance of the first G connected capacitor 91 becomes 0.5 times as much as [Cgs+Cgd]. In this case, as compared with the case in which the parasitic capacitance of the first G connected capacitor 91 is 0, the bandwidth of the amplifier becomes 0.83 times and the transfer gain of the signal passing through the first G connected capacitor 91 becomes 0.67 times. Therefore, the GD product becomes 0.56 times (=0.83×0.67). Therefore, the GD product in the case of a configuration including the compensating circuit 1 becomes 1.7 times (=0.56/0.33) as much as that in the case of a configuration not including the compensating circuit 1 and it is known that characteristics of the amplifier 9 may be improved. Since the first G connected capacitor 91 may be made small as compared with a configuration not including the compensating circuit 1, size reduction of the amplifier 9 may be achieved.

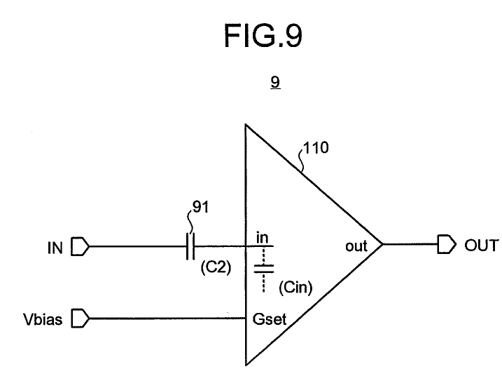

FIG. 9 is a circuit diagram of a generalized example of the amplifier. As shown in FIG. 9, in the amplifier 9, the first G connected capacitor 91 is connected to the input terminal in of the amplifying circuit 110. The input capacitor Cin corresponds to [Cgs+Cgd] of the amplifying transistor 90 shown in FIG. 2. The bias voltage Vbias is supplied from the stabilizer 7 to the gain setting terminal Gset of the amplifying circuit 110. The output terminal out of the amplifying circuit 110 is connected to the output terminal of the amplifier 9.

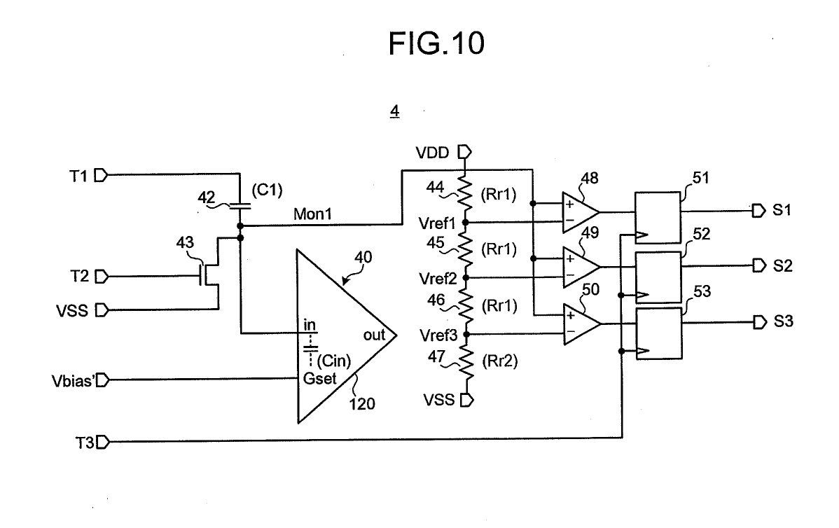

FIG. 10 is a circuit diagram of the detector in the case of generalizing the amplifier. As shown in FIG. 10, in the detector 4, in place of the third dummy amplifying transistor 41 shown in FIG. 4, the third dummy amplifying circuit 120 is adopted as the third dummy amplifier 40. The detector 4 shown in FIG. 10 is adopted in the compensating circuit 1 for the amplifier 9 shown in FIG. 9.

The third dummy amplifying circuit 120 is of an identical configuration to that of the amplifying circuit shown in FIG. 9 and includes the input capacitor Cin equivalent to the input capacitor Cin of the amplifying circuit 110. The input capacitor Cin of the third dummy amplifying circuit 120 corresponds to [Cgs+Cgd] of the third dummy amplifying transistor 41 shown in FIG. 4. The second G connected capacitor 42 and the drain terminal of the resetting transistor 43 are connected to the input terminal in of the third dummy amplifying circuit 120. An appropriate bias voltage Vbis′ is supplied to the gain setting terminal Gset of the third dummy amplifying circuit 120. The other configuration of the detector 4 is identical to the configuration shown in FIG. 4.

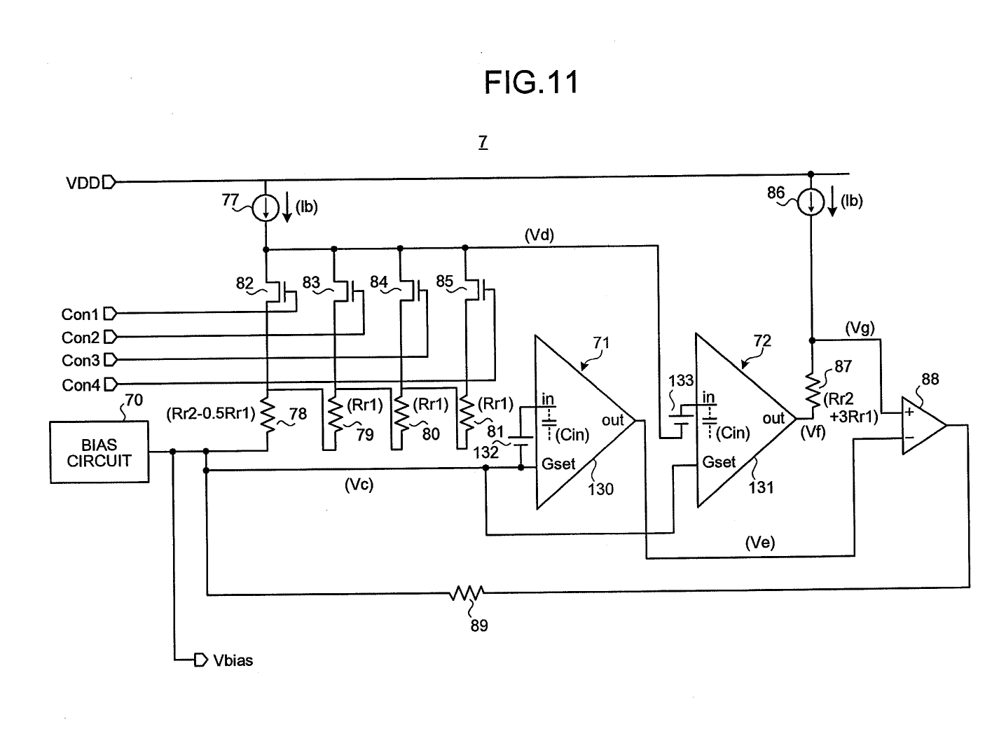

FIG. 11 is a circuit diagram of the stabilizer in the case of generalizing the amplifier. As shown in FIG. 11, the first dummy amplifying circuit 130 and the second dummy amplifying circuit 131 are adopted as the first dummy amplifier 71 and the second dummy amplifier 72, respectively. The stabilizer 7 shown in FIG. 11 is adopted in the compensating circuit 1 for the amplifier 9 shown in FIG. 9.

The first dummy amplifying circuit 130 and the second dummy amplifying circuit 131 are of an identical configuration to that of the amplifying circuit 110 shown in FIG. 9 and include the input capacitor Cin equivalent to the input capacitor Cin of the amplifying circuit 110. The input capacitor Cin of the first dummy amplifying circuit 130 corresponds to [Cgs+Cgd] of the first dummy amplifying transistor 74 shown in FIG. 6. The bias voltage Vc for setting the gain is supplied to the gain setting terminal Gset of the first dummy amplifying circuit 130. A voltage greater than Vc by a predetermined amount is supplied by the first voltage source 132 to the input terminal in of the first dummy amplifying circuit 130.

The input capacitor Cin of the second dummy amplifying circuit 131 corresponds to [Cgs+Cgd] of the second dummy amplifying transistor 76 shown in FIG. 6. The bias voltage Vc for setting the gain is supplied to the gain setting terminal Gset of the second dummy amplifying circuit 131. Principally, configuration should be such that, in the same way as in the stabilizer 7 shown in FIG. 6, Vd as the bias voltage for setting the gain is input to the gain setting terminal Gset of the second dummy amplifying circuit 131, where the gain of the amplifying circuit 110 shown in FIG. 9, the first dummy amplifying circuit 130, and the second dummy amplifying circuit 131 are equivalent.

Because of the voltage difference between Vc and Vd is minute, even if Vc is input to the gain setting terminal Gset of the second dummy amplifying circuit 131, the difference in gain is minute as compared with the case of inputting the Vd and in practice, no problem arises. Configuration may be such that Vd is input to the gain setting terminal Gset of the second dummy amplifying circuit 131. A voltage greater than Vd by a predetermined voltage is supplied by the second voltage source 133 to the input terminal in of the second dummy amplifying circuit 131. The voltage increase by the second voltage source 133 and the voltage increase by the first voltage source 132 are equivalent. Therefore, the difference between the voltage of the signal input to the input terminal in of the first dummy amplifying circuit 130 and that input to the input terminal in of the second dummy amplifying circuit 131 is [Vd−Vc]. The other configuration of the stabilizer 7 is identical to the configuration shown in FIG. 6.

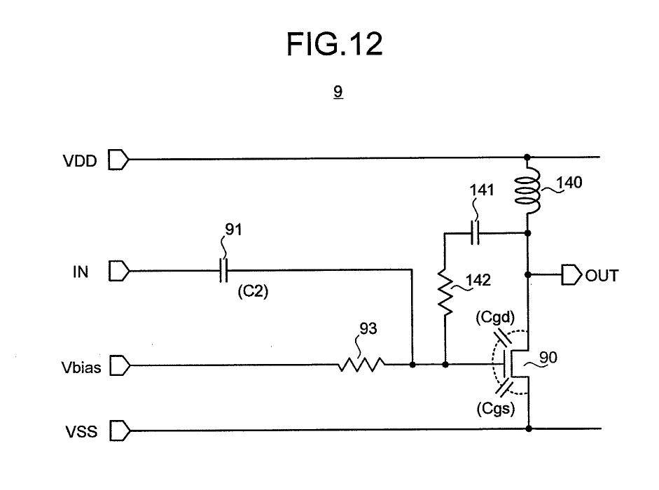

FIG. 12 is a circuit diagram of an example of the amplifier as a low-noise amplifying circuit. As shown in FIG. 12, in the amplifier 9, an inductor 140 in place of the resistor is connected as a load to the drain terminal of the amplifying transistor 90. The second capacitor 141 and the eighth resistor 142 are connected between the drain terminal and the gate terminal of the amplifying transistor 90. Configuration of the rest of the amplifier is identical to that shown in FIG. 2. The amplifying circuit including the amplifying transistor 90, the second resistor 93, the inductor 140, the second capacitor 141, and the eighth resistor 142 is adopted, for example, in a wireless device as a low-noise amplifying circuit (LNA) for reception.

In the compensating circuit 1 for the amplifier 9 shown in FIG. 12, when the stabilizer 7 shown in FIG. 6 is adopted, a difference arises in that the load of the amplifying transistor 90 is the inductor 140, while the loads of the first dummy amplifying transistor 74 and the second dummy amplifying transistor 76 are the third resistor 73 and the fourth resistor 75, respectively. However, since the variations of the resistor and the inductance are extremely small, no particular problem arises if design is made taking into consideration the impedance of the resistor and the inductor at the target frequency.

The present invention is not limited to the embodiments described above but may be modified in various ways. Modifications may be made so long as, for example, the ratio of the capacitance C1 of the second G connected capacitor 42 to the G-S parasitic capacitance Cgs and the G-D parasitic capacitance Cgd of the third dummy amplifying transistor 41 is equivalent to the ratio of the capacitance C2 of the first G connected capacitor 91 to the G-S parasitic capacitance Cgs and the G-D parasitic capacitance Cgd of the amplifying transistor 90.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. An attenuation compensating circuit comprising:
a detector that detects a degree of attenuation when a signal to be amplified passes through a capacitor; and
a stabilizer that controls a bias voltage supplied to an amplifier based on the degree of attenuation detected by the detector.

2. The attenuation compensating circuit according to claim 1, wherein
the detector includes
a dummy capacitor corresponding to the capacitor through which the signal to be amplified passes,
a plurality of reference voltages, and
a comparator that compares a voltage of a dummy signal passing through the dummy capacitor with the reference voltages, and
the detector, through comparison of the voltage of the dummy signal with the reference voltages by the comparator, detects the degree of attenuation of the dummy signal passing through the dummy capacitor.

3. The attenuation compensating circuit according to claim 2, wherein the detector includes a plurality of resistors and generates the reference voltages by voltage-dividing a predetermined voltage by the resistors.

4. The attenuation compensating circuit according to claim 1, wherein
the stabilizer includes
a first dummy amplifier for which gain is controlled by a first bias voltage and that amplifies a first input voltage and outputs a first output voltage; and
a second dummy amplifier for which gain is controlled by a second bias voltage and that amplifies a second input voltage and outputs a second output voltage, and
the stabilizer sets respectively a difference between the first bias voltage and the second bias voltage and a difference between the first input voltage and the second input voltage as a first voltage difference corresponding to the degree of attenuation detected by the detector, sets a difference between the first output voltage and the second output voltage as a second voltage difference, controls the first bias voltage so that a product of the first voltage difference and the gain of the first dummy amplifier is equivalent to the second voltage difference, and supplies the first bias voltage to the amplifier as a bias voltage for controlling gain.

5. The attenuation compensating circuit according to claim 1, wherein
the stabilizer includes
a first dummy amplifier for which gain is controlled by a bias voltage and that amplifies a first input voltage and outputs a first output voltage; and
a second dummy amplifier for which gain is controlled by the bias voltage and that amplifies a second input voltage and outputs a second output voltage, and
the stabilizer sets a difference between the first input voltage and the second input voltage as a first voltage difference corresponding to the degree of attenuation detected by the detector, sets a difference between the first output voltage and the second output voltage as a second voltage difference, controls the bias voltage so that a product of the first voltage difference and the gain of the first dummy amplifier is equivalent to the second voltage difference, and supplies the bias voltage to the amplifier as a bias voltage for controlling gain.

6. The attenuation compensating circuit according to claim 4, wherein the gain of the amplifier is controlled to a value equivalent to the second voltage difference divided by the first voltage difference.

7. The attenuation compensating circuit according to claim 5, wherein the gain of the amplifier is controlled to a value equivalent to the second voltage difference divided by the first voltage difference.

8. The attenuation compensating circuit according to claim 4, wherein the first voltage difference is generated by changing the number of resistors connected between an input terminal of the first dummy amplifier and an input terminal of the second dummy amplifier according to the degree of attenuation detected by the detector.

9. The attenuation compensating circuit according to claim 5, wherein the first voltage difference is generated by changing the number of resistors connected between an input terminal of the first dummy amplifier and an input terminal of the second dummy amplifier according to the degree of attenuation detected by the detector.
